(19) United States
(12) Patent Application Publication
(10) Pub. No.: US 2010/0132779 A1
(43) Pub. Date: Jun. 3, 2010

(54) SOLAR CELL AND METHOD OF FABRICATING THE SAME

(75) Inventors: Jin Hong, Gyeonggi-do (KR); Jae-Ho Kim, Gyeonggi-do (KR); Yong-Woo Shin, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD., Gyeonggi-do (KR)

(21) Appl. No.: 12/597,496

(22) PCT Filed: May 29, 2008
(86) PCT No.: PCT/KR08/03010

§ 371 Date: Oct. 25, 2009

(30) Foreign Application Priority Data
May 30, 2007 (KR) 10-2007-0052665
Oct. 31, 2007 (KR) 10-2007-0110332

(51) Int. Cl. H01L 31/0352; H01L 31/0232; H01L 31/18

(52) U.S. Cl. 136/255; 438/71; 257/E31.039; 257/E31.127

(57) ABSTRACT

A solar cell includes a first electrode on a substrate; a plurality of pillars on the first electrode; a semiconductor layer on the first electrode, wherein a surface area of the semiconductor layer is greater than a surface area of the first electrode; and a second electrode over the semiconductor layer.

### TECHNICAL FIELD

The present invention relates to a solar cell, and more particularly, to a solar cell having an improved light absorbing efficiency and a method of fabricating the solar cell.

### BACKGROUND ART

For response to exhaustion of fossil fuel and preventing environmental pollution, a clean energy source, e.g., solar energy, has been come into the spotlight. Particularly, the solar cell for converting solar energy into electric energy has been developed rapidly. The solar cell may be divided into a solar thermal cell and a photovoltaic solar cell. The solar thermal cell generates steam for rotating a turbine using solar thermal energy, while the photovoltaic solar cell converts solar photons into electric energy using semiconductors.

Among these solar cells, the photovoltaic solar cell, which absorbs light and converts the light into electric energy using an electron of a positive (P) type semiconductor and a hole of a negative (N) type semiconductor, is developed widely. Hereinafter, the photovoltaic solar cell is referred to as a solar cell.

The solar cell using the semiconductors has the substantially same structure as PN junction diode. When light is irradiated on a portion between the P type semiconductor and the N type semiconductor, the electron and the hole are induced in the semiconductors due to light energy. Generally, when light having energy smaller than band gap energy of the semiconductor is irradiated, the hole and the electron has a weak interaction. On the other hand, when light having energy greater than band gap energy of the semiconductor is irradiated, the electron in a covalent bond is exited to form an electron-hole pair as a carrier. The carrier generated by light has a steady-state by recombination. The electron and the hole, which are generated by light, are transferred into the N type semiconductor and the P type semiconductor, respectively, by an inside electric field. Accordingly, the electron and the hole are concentrated on facing electrodes, respectively, to be used as a power.

On the other hand, a thin film of the semiconductor is formed by one of a vapor phase growth method, a spray pyrolysis method, a zone melting re-crystallization method, a solid phase crystallization method, and so on. The zone melting re-crystallization method and the solid phase crystallization method have a relatively high efficiency. However, since they have a high process temperature, a substrate of glass or metallic material can not be available. They require a substrate having a high heat stability such that production costs increases. To meet requirements in production costs, an amorphous silicon thin film or a polycrystalline compound thin film are deposited by the vapor phase growth method or the spray pyrolysis method. However, they have poor efficiency, for example, less than about 10%. Accordingly, it is required to study a method of fabricating a solar cell having high efficiency and being available on a glass substrate.

FIG. 1 is a cross-sectional view of the related art solar cell. Referring to FIG. 1, the solar cell 10 includes a substrate 12 and a transparent conductive oxide electrode 14, a P type semiconductor layer 16, an intrinsic semiconductor layer 18, an N type semiconductor layer 20 and a metal electrode 22 stacked on the substrate 12.

The related art solar cell has a flat shape. Accordingly, when the intrinsic semiconductor as an active layer absorbs light through the substrate and the transparent conductive oxide electrode to generate an electrode-hole pair, the intrinsic semiconductor should be formed to be thick or a dual cell having a laminated junction structure, for example, a tandem structure, is required for increasing an amount of absorbed light.

### DISCLOSURE OF INVENTION

### Technical Problem

As mentioned above, to increase an amount of light absorbed by the intrinsic semiconductor layer as an active layer, there are some cases. For example, the solar cell has a thicker intrinsic semiconductor layer. However, it causes problems of increase of production costs and production time. On the other hand, the solar cell having an intrinsic semiconductor layer as a dual cell, which has a laminated junction structure, is provided. However, it causes problems of increase of production costs and production time, and there is increased possibility of deterioration.

### Technical Solution

Accordingly, embodiments of the invention is directed to a solar cell and a method of fabricating the same that substantially obviate one or more of the problems due to limitations and disadvantages of the related art are described.

An object of the embodiments of the invention is to provide a solar cell having an intrinsic semiconductor layer as an active layer, which absorbs increased amount of light, and a method of fabricating the solar cell.

To achieve these and other advantages and in accordance with the purpose of embodiments of the invention, as embodied and broadly described, a solar cell includes a first electrode on a substrate; a plurality of pillars on the first electrode; a semiconductor layer on the first electrode, wherein a surface area of the semiconductor layer is greater than a surface area of the first electrode; and a second electrode over the semiconductor layer.

In another aspect, a method of fabricating a solar cell includes forming a first electrode on a substrate; forming a plurality of pillars on the first electrode; forming a semiconductor layer on the first electrode, wherein a surface area of the semiconductor layer is greater than a surface area of the first electrode; and forming a second electrode over the semiconductor layer.

In another aspect, a solar cell includes a plurality of pillars on a surface of a substrate; a first electrode on the surface of the substrate having the plurality of pillars; a semiconductor layer on the first electrode, wherein a surface area of the semiconductor layer is greater than a surface area of the substrate; and a second electrode over the semiconductor layer.

In another aspect, a method of fabricating a solar cell includes forming a plurality of pillars on a surface of the substrate; forming a first electrode on the surface of the substrate having the plurality of pillars; forming a semiconductor layer on the first electrode, wherein a surface area of the semiconductor layer is greater than a surface area of the substrate; and forming a second electrode over the semiconductor layer.

### ADVANTAGEOUS EFFECTS

In a solar cell and a method of fabricating the same according to the present invention, there is a plurality of pillars that forms a step difference. Since a semiconductor layer, for example, an intrinsic semiconductor layer, is formed on the plurality of pillars, the semiconductor layer has a step difference due to the step difference. As a result, a surface area of the semiconductor layer is greater than a surface area of a layer, for example, a substrate under the semiconductor layer, having an even surface. Accordingly, the semiconductor can absorb an increased amount of light, and the solar cell can provide an increased amount of electromotive force.

### BRIEF DESCRIPTION OF THE DRAWINGS

The accompanying drawings, which are included to provide a further understanding of embodiments of the invention and are incorporated in and constitute a part of this specification, illustrate embodiments of the invention and together with the description serve to explain the principles of embodiments of the invention. In the drawings:

FIG. 1 is a cross-sectional view of the related art solar cell;

FIG. 2 is a cross-sectional view of a solar cell according to a first embodiment of the present invention;

FIG. 3 is a plan view of a solar cell according to a first embodiment of the present invention;

FIGS. 4 and 5 are cross-sectional views showing a fabricating process of a solar cell according to a first embodiment of the present invention;

FIG. 6 is a plan view of a solar cell according to a second embodiment of the present invention;

FIG. 7 is a cross-sectional view of a solar cell according to a third embodiment of the present invention;

FIGS. 8 to 11 are cross-sectional views showing a fabricating process of a solar cell according to a third embodiment of the present invention;

FIGS. 12 to 14 are plan views of a pillar in a solar cell according to third, fourth and fifth embodiments of the present invention, respectively;

FIG. 15 is a schematic view showing a sandblasting process according to the present invention; and

FIGS. 16 and 17 are cross-sectional views showing a fabricating process of a solar cell using a paste according to the present invention.

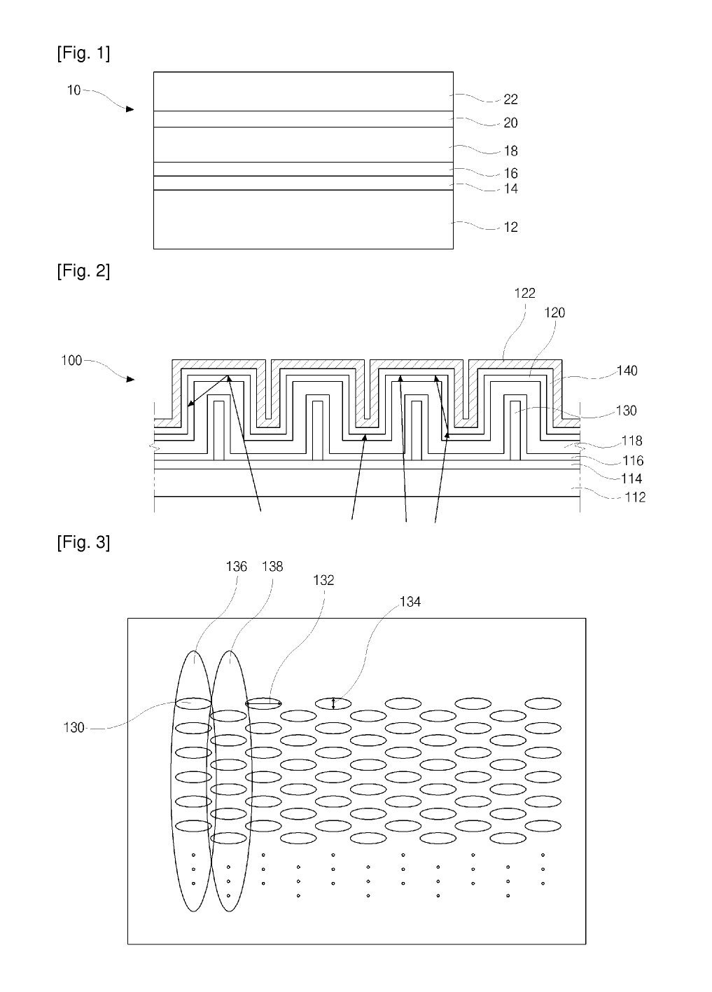

### BEST MODE FOR CARRYING OUT THE INVENTION

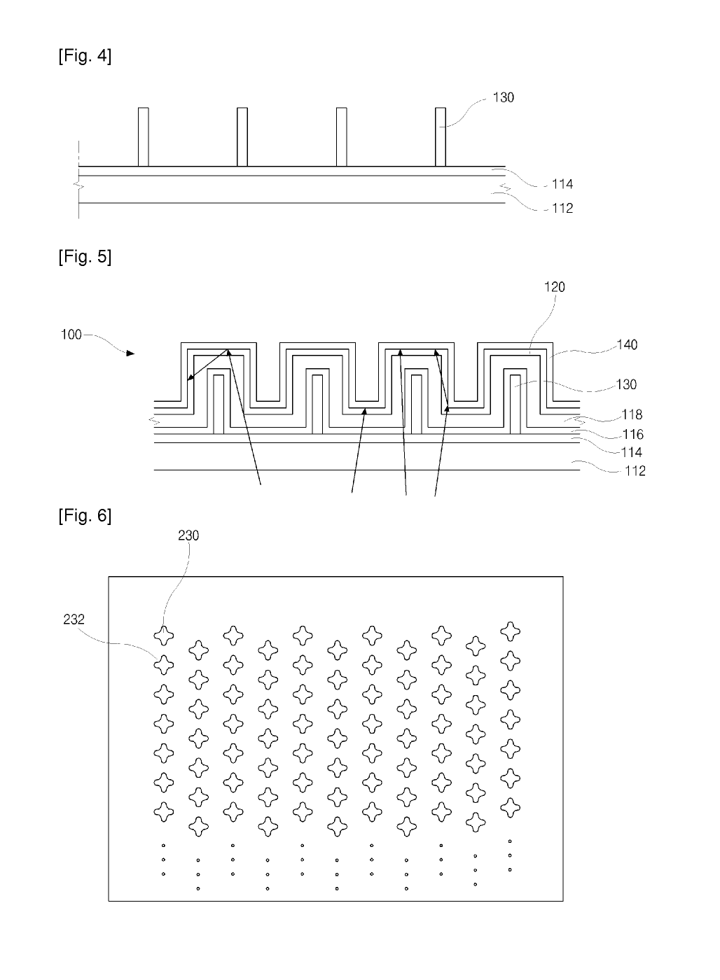

FIG. 2 is a cross-sectional view of a solar cell according to a first embodiment of the present invention, FIG. 3 is a plan view of a solar cell according to a first embodiment of the present invention, and FIGS. 4 and 5 are cross-sectional views showing a fabricating process of a solar cell according to a first embodiment of the present invention.

Referring to FIG. 2, a solar cell 100 includes a substrate 112, a first electrode 114, a plurality of pillars 130, a first semiconductor layer 116, an intrinsic semiconductor layer 118, a second semiconductor layer 120, a reflective layer 140 and a second electrode 122. The substrate 112 may be formed of transparent glass and have an insulating property. The first electrode 114 may be formed of a transparent conductive oxide material, for example, indium-tin-oxide (ITO) or indium-zinc-oxide (IZO) and disposed on the substrate 112. The plurality of pillars 130 have a cylinder shape and are disposed on the first electrode 114. The first semiconductor layer 116 has a positive (P) type and formed on the first electrode 114 and the plurality of pillars 130. Namely, a P type impurity is doped into the first semiconductor layer 116. The intrinsic semiconductor layer 118 functions as an active layer and is disposed on the first semiconductor layer 116. Namely, no impurity is doped into the intrinsic semiconductor layer 118. Since the pillars 130 protrude from the first electrode 114, not only the first semiconductor layer 116 but also the intrinsic semiconductor layer 118 has a step difference. The intrinsic semiconductor layer 118 has a concave portion and a convex portion. The convex portion corresponds to each of the pillars 130, and the concave portion disposed between adjacent convex portions. Namely, the substrate 112 and the first electrode 114 have an even surface, while the intrinsic semiconductor layer 118 has an uneven surface. Accordingly, a surface area of the intrinsic semiconductor layer 118 is greater than that of the first electrode 114 and the substrate 112. Since the intrinsic semiconductor layer 118 has an increased surface area, an amount of light absorbed by the intrinsic semiconductor layer 118 increases. Accordingly, the solar cell can provide an increased amount of electromotive force. The second semiconductor layer 120 has a negative (N) type and is disposed on the intrinsic semiconductor layer 118. Namely, an N type impurity is doped into the second semiconductor layer 120. The reflective layer 140 is disposed on the second semiconductor layer 120, and the second electrode 122 formed of a metallic material is disposed on the reflective layer 140.

The first electrode 114 is formed on a first surface of the substrate 112. Light is incident on a second surface, which is opposite to the first surface, of the substrate 112 and transferred to the first electrode 114. Light passing through the substrate 112 is incident on the intrinsic semiconductor layer 118 through the first electrode 114 and the first semiconductor layer 116. The first electrode 114 is formed to obtain an ohmic contact with the first semiconductor layer 116. Carrier generated in the intrinsic semiconductor layer 118 by light is induced into the first electrode 114 by the first semiconductor layer 116. As mentioned above, the first semiconductor layer 116 has the P type. The intrinsic semiconductor layer 118 as the active layer absorbs light to generate the carrier. Namely, the intrinsic semiconductor layer 118 is formed of an intrinsic semiconductor material. The carrier generated in the intrinsic semiconductor layer 118 is induced into the second electrode 120 by the second semiconductor layer 120. As mentioned above, the second electrode 120 has the N type. The reflective layer 140 reflects the light, which is incident through the substrate 112, such that light is incident again on the intrinsic semiconductor layer 118. A line (not shown) is connected to the second electrode 122 to obtain an electromotive force.

Referring to FIG. 3, the plurality of pillars 130 having a cylinder shape are disposed on the first electrode 114 (of FIG. 2) of a transparent conductive oxide material. A distance between two adjacent pillars 130 is determined depending on a respective thickness of various layers stacked over the pillars 130. The pillars 130 is formed to maximize a surface area of the intrinsic semiconductor 118 (of FIG. 2) exposed to light. Each of the pillars 130 may have different cross-sectional shape and different arrangement than that of FIG. 2. For example, referring to FIG. 6 showing a plan view of a solar cell according to a second embodiment of the present invention, the pillars 230 may have a cross shape in plan. In the cross shape pillar 230, a connecting line between one end of one axis and ends of the other axis has a curved shape 232. Referring back to FIG. 3, the pillars 130 have an oval shape of a major axis 132 and a minor axis 134. The pillars 130 are arranged to be spaced apart from each other by a pre-determined space. The pillar 130 in a second column 138 is located to correspond to a space between adjacent pillars 130 in a first column 136. Namely, the pillars 130 in the first column 136 and the pillars 130 in the second columns 138 are alternately arranged.

A method of fabricating a solar cell according to a first embodiment of the present invention is explained with reference to FIGS. 4 and 5. Referring to FIG. 4, a first electrode 114 is formed on a substrate 112 by depositing a transparent conductive material. For example, the transparent conductive material is deposited by a chemical vapor deposition (CVD) method using tin oxide (SnO2) or zinc oxide (ZnO). Next, a silicon oxide (SiO2) layer (not shown) having a transparent property is deposited on the first electrode 114. Then, the silicon oxide layer (not shown) is patterned by a photolithography to form a plurality of pillars 130. The pillars 130 may be formed of silicon nitride (SiNx) or photoresist. Both silicon nitride (SiNx) and photoresist have a transparent property. To maximize a surface area exposed to light of the intrinsic semiconductor layer (not shown), the pillars 130 is formed of a transparent material having a high optical transmittance. Moreover, the pillars 130 are arranged to have compact formation.

Referring to FIG. 5, a first semiconductor layer 116 is formed on the first electrode 114 including the pillars 130 by depositing a P type semiconductor material, where P type impurities are doped, using a plasma enhanced chemical vapor deposition (PECVD) method. The first semiconductor layer 116 has a step due to the pillars 130.

Next, an intrinsic semiconductor layer 118 is formed on the first semiconductor layer 116 by depositing an intrinsic semiconductor material where no impurity is doped. Since the first semiconductor layer 116 has a step, the intrinsic semiconductor layer 118 also has a step. Accordingly, a surface area of the intrinsic semiconductor layer 118 increases. Next, a second semiconductor layer 120 is formed on the intrinsic semiconductor layer 118 by depositing an N type semiconductor material where N type impurities are doped. Next, a reflective layer 140 is formed on the second semiconductor layer 120 by depositing a reflective material, for example, zinc oxide (ZnO). Although not shown, a second electrode is formed on the reflective layer 140. The second electrode is formed an opaque metallic material, for example, aluminum (Al).

The substrate 112, the first electrode 114 and the reflective layer 140 is treated with a texturing process to have trapping properties for light. By the texturing process, most of light, which is incident on the substrate 112, is absorbed onto the intrinsic semiconductor layer 118. Namely, the texturing process prevents light being flowed off outside of the solar cell. In more detail, light passing through the substrate 112 is trapped between the first electrode 114 and the reflective layer 140. The trapped light is absorbed onto the intrinsic semiconductor layer 118.

The intrinsic semiconductor layer 118 absorbs light directly incident to the intrinsic semiconductor layer 118 through the substrate 112 and reflected on the reflective layer 140 where the texturing process is performed. Since the intrinsic semiconductor layer 118 has an increasing surface area due to the pillars 130, efficiency of generating an electron-hole pair is improved. Compared with the intrinsic semiconductor layer 118 in related art solar cell, the intrinsic semiconductor layer 118 in the solar cell of the present invention has an increasing surface area with the same cross-sectional area and the same thickness. Accordingly, the solar cell has improved efficiency.

### MODE FOR THE INVENTION

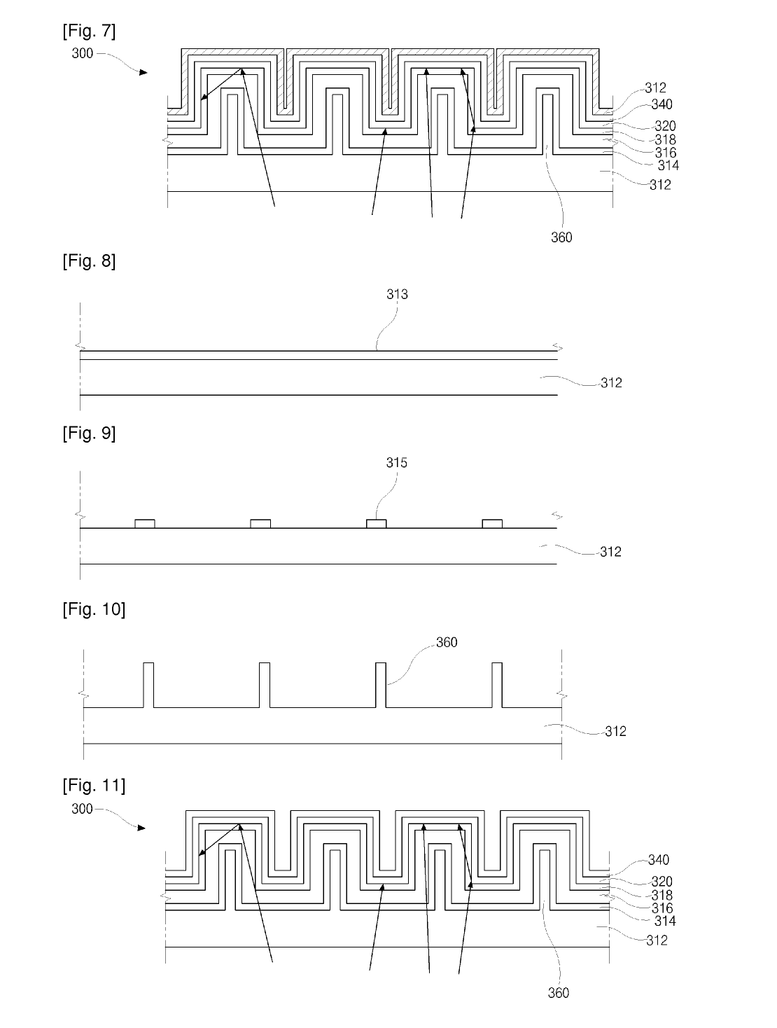

FIG. 7 is a cross-sectional view of a solar cell according to a third embodiment of the present invention, and FIGS. 8 to 11 are cross-sectional views showing a fabricating process of a solar cell according to a third embodiment of the present invention.

Referring to FIG. 7, a solar cell 300 includes a substrate 312 having a plurality of pillars 360, a first electrode 314, a first semiconductor layer 316, an intrinsic semiconductor layer 318, a second semiconductor layer 320, a reflective layer 340 and a second electrode 322. The plurality of pillars 360 are formed by etching portions of substrate 312 to protrude from a first surface of the substrate 312. Since the pillars 360 protrude from the substrate 312, not only the first electrode 314 and the first semiconductor layer 316 but also the intrinsic semiconductor layer 318 has a step difference. The intrinsic semiconductor layer 318 has a concave portion and a convex portion. The convex portion corresponds to each of the pillars 360, and the concave portion disposed between adjacent convex portions. Namely, the substrate 312 has an even surface, while the intrinsic semiconductor layer 318 has an uneven surface. Accordingly, a surface area of the intrinsic semiconductor layer 318 is greater than that of the substrate 312.

The substrate 312 may be formed of transparent glass and have an insulating property. The first electrode 314 may be formed of a transparent conductive oxide material, for example, indium-tin-oxide (ITO) or indium-zinc-oxide (IZO) and disposed on the substrate 312. The first semiconductor layer 316 has a positive (P) type and formed on the first electrode 314. The intrinsic semiconductor layer 318 functions as an active layer and is disposed on the first semiconductor layer 316. The second semiconductor layer 320 has a negative (N) type and is disposed on the second semiconductor layer 320. The reflective layer 340 is disposed on the second semiconductor layer 320, and the second electrode 322 formed of a metallic material is disposed on the reflective layer 340. Since the plurality of pillars 360 is formed by etching portions of the substrate 312, a fabricating process is simplified with compared to that of the first embodiment. Because the intrinsic semiconductor layer 318 has a step due to the pillars 360, the intrinsic semiconductor layer 318 has an increasing surface area.

A method of fabricating the solar cell according to the second embodiment is explained with reference to FIGS. 8 to 11. Referring to FIG. 8, a photosensitive material layer 313 is formed on a first surface of a substrate 312. Next, referring to FIG. 9, a plurality of photosensitive material patterns 315 are formed on the first surface of the substrate 312. Each of the photosensitive material patterns 315 has an island shape.

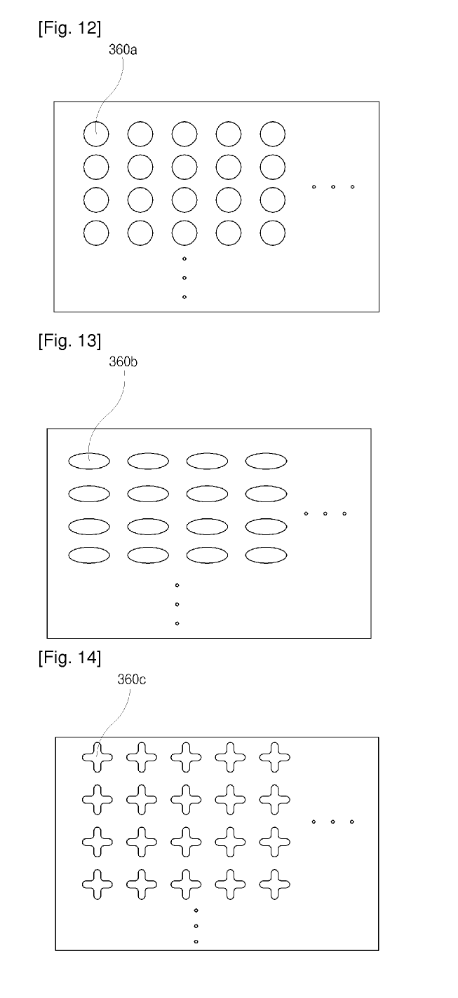

Referring to FIG. 10, the substrate 312 is patterned using the plurality of photosensitive material patterns 315 (of FIG. 9) as a pattering mask by a sandblasting process to form a plurality of pillars 360. The pillars 360 correspond to the photosensitive material patterns 315 (of FIG. 9). Referring to FIGS. 12 to 14 showing various shapes of the pillars in plan, the plan view of the pillars 360 has one of circular shape 360a in FIG. 12, an oval shape 360b in FIG. 13 and a cross shape 360c in FIG. 14. In FIGS. 12 to 14, the pillars 360 are arranged in a matrix shape. However, the pillars 360 may be arranged in other shape. For example, as shown in FIG. 3, the pillar in a second virtual line is located to correspond to a space between two adjacent pillars in a first virtual line.

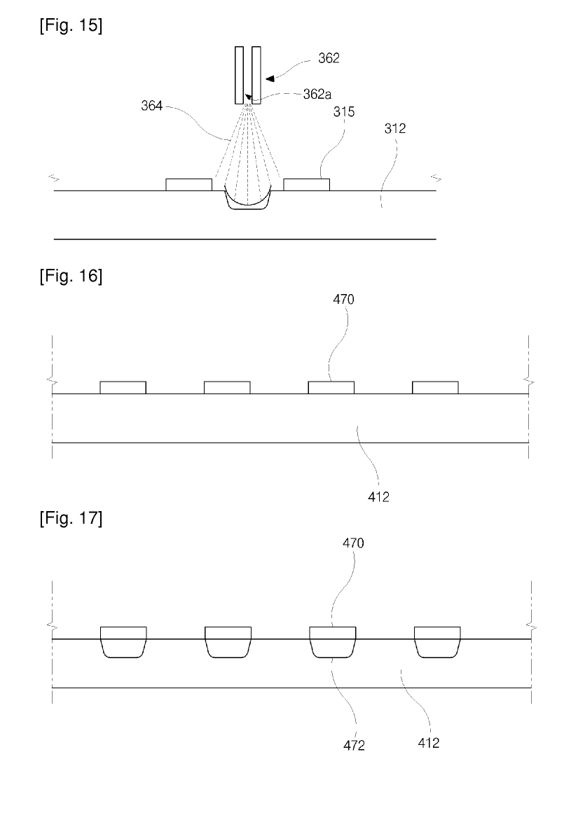

Referring to FIG. 15 showing a sandblasting process, a sandblaster 362 having a nozzle 362a is disposed over the substrate including the photosensitive material patterns 315. Abrasive particles 364 of aluminum oxide (Al2O3) are sprayed onto the substrate 312 through the nozzle 362a. Portions of the substrate exposed by the photosensitive material patterns 315 are etched by the abrasive particles 364 such that each of the pillars 160 are formed under each of the photosensitive material patterns 315. Namely, the substrate 312 is etched using the photosensitive material patterns 315 as an etching mask. Instead of the photosensitive material patterns 315, a dry film resist (DFR) may be laminated on the substrate 312. The DFR is exposed using a mask (not shown) and developed to form a plurality of DFR patterns. The DFR patterns function as an etching mask for the substrate 312.

Next, referring to FIG. 11, a first electrode 314 is formed on a substrate 312 having the pillars 360 by depositing a transparent conductive material. For example, the transparent conductive material is deposited by a chemical vapor deposition (CVD) method using tin oxide (SnO2) or zinc oxide (ZnO). A first semiconductor layer 316 is formed on the first electrode 314 by depositing a P type semiconductor material, where P type impurities are doped, using a plasma enhanced chemical vapor deposition (PECVD) method. The first semiconductor layer 316 has a step due to the pillars 130. Next, an intrinsic semiconductor layer 318 is formed on the first semiconductor layer 316 by depositing an intrinsic semiconductor material where no impurity is doped. Since the first semiconductor layer 316 has a step, the intrinsic semiconductor layer 318 also has a step. Accordingly, a surface area of the intrinsic semiconductor layer 318 increases. Next, a second semiconductor layer 320 is formed on the intrinsic semiconductor layer 318 by depositing an N type semiconductor material where N type impurities are doped. Next, a reflective layer 340 is formed on the second semiconductor layer 320 by depositing a reflective material, for example, zinc oxide (ZnO). Although not shown, a second electrode 322 (of FIG. 7) is formed on the reflective layer 340. The second electrode 322 (of FIG. 7) is formed an opaque metallic material, for example, aluminum (Al).

FIGS. 16 and 17 are cross-sectional views showing a fabricating process of a solar cell using a paste according to the present invention. Referring to FIG. 16, a paste pattern 470 having a gel state is formed on a substrate 412 by a screen printing method. The paste pattern 470 has a plurality of openings. Next, referring to FIG. 17, a material of the paste pattern 470 has a reaction with the substrate 412 of glass to form a reaction portion 472. Namely, a portion 470 under the paste pattern 470 is altered by the reaction with the material of the paste pattern 470 such that the reaction portion 472 of the substrate 412 is disposed under the paste pattern 470. The reaction portion 472 has a different property than other portions of the substrate 312. Although not shown, the reaction portion 472 and the paste pattern 470 are removed to form a plurality of pillars. Since the reaction portion 472 under the paste pattern 470 is removed, each of the plurality of pillars corresponds to each of the plurality of openings. Moreover, a first electrode, a first semiconductor layer, an intrinsic semiconductor layer, a second semiconductor layer, a reflective layer and a second electrode are stacked on the substrate 412 having the pillars.

It will be apparent to those skilled in the art that various modifications and variations can be made in the apparatus having an edge frame without departing from the spirit or scope of the invention. Thus, it is intended that the present invention covers the modifications and variations of this invention provided they come within the scope of the appended claims and their equivalents.

### INDUSTRIAL APPLICABILITY

In the present invention, a solar cell has improved ability because a semiconductor layer of the solar cell has an increased surface area. The solar cell is available as an energy source without problems, for example, environment pollution.

1. A solar cell, comprising:
a first electrode on a substrate;
a plurality of pillars on the first electrode;
a semiconductor layer on the first electrode, wherein a surface area of the semiconductor layer is greater than a surface area of the first electrode; and
a second electrode over the semiconductor layer.

2. The solar cell according to claim 1, wherein the semiconductor layer includes a first semiconductor layer of a positive type impurity-doped semiconductor material, a second semiconductor layer of an intrinsic semiconductor material, and a third semiconductor layer of a negative type impurity-doped semiconductor material, and wherein the first semiconductor layer faces the plurality of pillars, and the second semiconductor layer is disposed between the first and third semiconductor layers.

3. The solar cell according to claim 2, wherein the substrate is formed of glass, the first electrode is formed of one of tin oxide and zinc oxide, and the second electrode is formed of an opaque metallic material.

4. The solar cell according to claim 2, further comprising a reflective layer disposed between the third semiconductor layer and the second electrode.

5. The solar cell according to claim 4, wherein the reflective layer is formed of zinc oxide.

6. The solar cell according to claim 1, wherein each of the plurality of pillars includes one of circular shape, an oval shape and a cross shape.

7. The solar cell according to claim 1, wherein each of the plurality of pillars has a cross shape having a first axis and a second axis, and further comprises a connecting line connecting one end of the first axis of the cross shape and ends of the second axis of the cross shape has a curved shape.

8. The solar cell according to claim 1, wherein the plurality of pillars are arranged in a first column and a second column, and wherein the pillars in the first column and the pillars in the second columns are alternately arranged.

9. The solar cell according to claim 1, wherein the plurality of pillars are formed of one of silicon oxide, silicon nitride and a transparent photosensitive material.

10. A method of fabricating a solar cell, comprising:
forming a first electrode on a substrate;
forming a plurality of pillars on the first electrode;
forming a semiconductor layer on the first electrode, wherein a surface area of the semiconductor layer is greater than a surface area of the first electrode; and
forming a second electrode over the semiconductor layer.

11. The method according to claim 10, wherein the step of forming the semiconductor layer includes forming a first semiconductor layer of a positive type impurity-doped semiconductor material facing the plurality of pillars, forming a second semiconductor layer of an intrinsic semiconductor material on the first semiconductor layer, and forming a third semiconductor layer of a negative type impurity-doped semiconductor material on the second semiconductor layer.

12. The method according to claim 11, further comprising forming a reflective layer between the third semiconductor layer and the second electrode.

13. A solar cell, comprising:
a plurality of pillars on a surface of a substrate;
a first electrode on the surface of the substrate having the plurality of pillars;
a semiconductor layer on the first electrode, wherein a surface area of the semiconductor layer is greater than a surface area of the substrate; and
a second electrode over the semiconductor layer.

14. The solar cell according to claim 13, wherein the semiconductor layer includes a first semiconductor layer of a positive type impurity-doped semiconductor material, a second semiconductor layer of an intrinsic semiconductor material, and a third semiconductor layer of a negative type impurity-doped semiconductor material, and wherein the first semiconductor layer faces the first electrode, and the second semiconductor layer is disposed between the first and third semiconductor layers.

15. The solar cell according to claim 14, wherein the substrate is formed of glass, the first electrode is formed of one of tin oxide and zinc oxide, and the second electrode is formed of an opaque metallic material.

16. The solar cell according to claim 14, further comprising a reflective layer disposed between the third semiconductor layer and the second electrode.

17. The solar cell according to claim 16, wherein the reflective layer is formed of zinc oxide.

18. The solar cell according to claim 13, wherein each of the plurality of pillars includes one of circular shape, an oval shape and a cross shape.

19. The solar cell according to claim 13, wherein each of the plurality of pillars has a cross shape having a first axis and a second axis, and further comprising a connecting line connecting one end of the first axis of the cross shape and ends of the second axis of the cross shape has a curved shape.

20. The solar cell according to claim 13, wherein the plurality of pillars are formed of the same material as the substrate.

21. The solar cell according to claim 13, wherein the plurality of pillars are arranged in a first column and a second column, and wherein the pillars in the first column and the pillars in the second columns are alternately arranged.

22. A method of fabricating a solar cell, comprising:
forming a plurality of pillars on a surface of the substrate;
forming a first electrode on the surface of the substrate having the plurality of pillars;
forming a semiconductor layer on the first electrode, wherein a surface area of the semiconductor layer is greater than a surface area of the substrate; and
forming a second electrode over the semiconductor layer.

23. The method according to claim 22, wherein the step of forming the plurality of pillars includes etching portions of the surface of the substrate such that each of the plurality of pillars corresponds to a portion between adjacent etched portions of the surface of the substrate.

24. The method according to claim 23, wherein the step of etching the portions of the surface of the substrate includes:
forming a plurality of etching mask patterns on the surface of the substrate, each of the plurality of etching mask patterns corresponding to each of the plurality of pillars; and
etching the portions of the surface of the substrate using the plurality of etching mask patterns as an etching mask.

25. The method according to claim 24, wherein the plurality of etching mask patterns are formed of one of a photosensitive material and a dry film resist.

26. The method according to claim 24, wherein the step of etching the portions of the surface of the substrate is performed by a sandblasting method.

27. The method according to claim 23, wherein the step of etching the portions of the surface of the substrate includes:
forming a paste pattern having a plurality of openings, wherein a material of the paste pattern has a reaction with a material of the substrate to form a reaction portion in the substrate under the paste pattern, and wherein each of the plurality of pillars corresponds to each of the plurality of openings; and
removing the reaction portion and the paste pattern.

28. The method according to claim 22, wherein the step of forming the semiconductor layer includes forming a first semiconductor layer of a positive type impurity-doped semiconductor material facing the plurality of pillars, forming a second semiconductor layer of an intrinsic semiconductor material on the first semiconductor layer, and forming a third semiconductor layer of a negative type impurity-doped semiconductor material on the second semiconductor layer.

29. The method according to claim 28, further comprising forming a reflective layer between the third semiconductor layer and the second electrode.
